(19) United States
(12) Patent Application Publication
(10) Pub. No.: US 2008/0050892 A1
(43) Pub. Date: Feb. 28, 2008

(54) Method of manufacturing a thin film structure, method of manufacturing a storage node using the same, method of manufacturing a phase change random access memory using the same and a thin film structure, a storage node and a phase change random access memory formed using the same

(75) Inventors: Woong-Chul Shin, Suwon-si (KR); Youn-Seon Kang, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/723,103

(22) Filed: Mar. 16, 2007

(30) Foreign Application Priority Data
Jun. 21, 2006 (KR) 10-2006-0055912

(51) Int. Cl. H01L 21/20; H01L 21/36

(52) U.S. Cl. 438/486

(57) ABSTRACT

Provided are a method of manufacturing a thin film structure, a method of manufacturing a storage node having the same, a method of manufacturing a phase-change random access memory device having the same and a thin film structure, storage node and phase-change random access memory device formed using the same. The method of manufacturing the thin film structure may include the operations of obtaining a seed layer formed of a chalcogenide alloy, by supplying one or two selected from the group consisting of a Group IV-precursor, a Group V-precursor, and a Group VI-precursor to an upper surface of an amorphous material layer, and forming the thin film by supplying a Group IV-precursor, a Group V-precursor, and a Group VI-precursor to an upper surface of the seed layer.

### PRIORITY STATEMENT

This application claims priority under 35 U.S.C. § 119 to Korean Patent Application No. 10-2006-0055912, filed on Jun. 21, 2006, in the Korean Intellectual Property Office (KIPO), the entire contents of which are incorporated herein by reference.

### BACKGROUND

1. Field

Example embodiments relate to a method of manufacturing a thin film structure, a method of manufacturing a storage node using the same, a method of manufacturing a phase-change random access memory device using the same and a thin film structure, a storage node and a phase change random access memory formed using the same.

2. Description of the Related Art

Phase-change random memory devices (hereinafter, referred to as PRAMs) are devices that memorize binary information by using characteristics that a phase change material (e.g., GeSbTe) may be changed to a crystalline state and an amorphous state due to local heat generation caused by an electrical pulse. In these PRAMs, a memory cell that memorizes the binary information may be made up of a phase-change layer, a bottom electrode contact (BEC) layer and a switch transistor. The switch transistor may be formed on a silicon wafer, and the BEC layer and the phase-change layer may be formed on the switch transistor. The phase-change layer may be formed of a GST (GeSbTe) base material. The GST (GeSbTe) base material may be a material of the same type as what is used in an optical recording apparatus (e.g., DVD and/or CD-RW), for example, chalcogenide. The bottom electrode contact layer may be used to heat up the phase-change layer. According to the degree by which the phase-change layer is heated, the state of the phase-change layer may be changed to the crystalline and amorphous states, and thus the resistance thereof may also be changed. Because a current or a voltage of the phase-change layer is changed due to the change in resistance, binary information may be stored and read. DRAM, which is a volatile memory, or a flash memory, which is a nonvolatile memory, may store the binary information in the form of a charge (e.g., charge-based memory), whereas PRAM may store the binary information in the form of a resistance (e.g., resistance-base memory). PRAM may be distinguished from the other memory devices.

PRAMs may have a binary state signal rate, which is one of the bases for estimating the functionality of storing binary information, higher than those of the other memory devices. Accordingly, a circuit may determine the binary information and may not require a relatively high voltage to perform this determination. When the binary state signal rate is represented as a resistance rate, the resistance rate may be about 40 times or higher, so that a wide dynamic range may be secured. The wide dynamic range may not be affected by the size of a memory node. Although the integration technology of semiconductor circuits is continuously progressed, the scalability of PRAM may be improved. PRAM may have a writing rate about ten or more times greater than that of flash memory because the phase-change speed of the phase-change layer may be relatively high.

In a process for manufacturing a conventional PRAM, when a GeSbTe material is deposited on an amorphous oxide film like a SiON and/or SiO₂ film using a general thermal MOCVD process, nuclear creation/growth may be relatively difficult, so that the manufacture of a thin film may be relatively difficult and, although the GeSb thin film is manufactured, its crystallinity and surface morphology may not be improved. In a recently developed PRAM, a GeSbTe material may be deposited on an insulating layer formed of SiON and/or SiO₂ and a bottom electrode contact layer formed of TiAlN and/or TiN at the same time. Different deposition behaviors may occur on the insulating layer and the bottom electrode contact layer upon deposition of the thin film, so that forming a uniform thin film may be relatively difficult. There may remain a demand for a process for forming an improved-quality thin film with improved crystallinity and surface morphology on an amorphous oxide film.

### SUMMARY

Example embodiments relate to a method of manufacturing a thin film structure, a method of manufacturing a storage node using the same, a method of manufacturing a phase-change random access memory device using the same and a thin film structure, a storage node and a phase change random access memory formed using the same.

According to example embodiments, a method of manufacturing a thin film structure may include obtaining a seed layer formed of a chalcogenide alloy, by supplying one or two selected from the group consisting of a Group IV-precursor, a Group V-precursor, and a Group VI-precursor to an upper surface of an amorphous material layer; and forming the thin film by supplying a Group IV-precursor, a Group V-precursor, and a Group VI-precursor to an upper surface of the seed layer.

According to example embodiments, a method of manufacturing a storage node may include forming a bottom electrode, forming an insulating film on the bottom electrode, forming a contact hole exposing a given area of the bottom electrode in the insulating film, forming a bottom electrode contact in the contact hole, manufacturing the thin film structure according to example embodiments and forming a top electrode on the thin film structure.

According to example embodiments, a method of manufacturing a phase-change random access memory (PRAM) may include a thin film switching device formed on a substrate and the storage node according to example embodiments connected to the thin film switching device.

According to example embodiments, a thin film structure may include a seed layer including a chalcogenide alloy on an upper surface of an amorphous material layer and a thin film on an upper surface of the seed layer.

According to example embodiments, a storage node may include a bottom electrode, an insulating film on the bottom electrode, a bottom electrode contact in a contact hole through the insulating film, the thin film structure according to example embodiments on the bottom electrode contact and a top electrode on the thin film structure.

According to example embodiments, a phase-change random access memory (PRAM) may include a thin film switching device on a substrate and the storage node according to example embodiments connected to the thin film switching device.

The seed layer may be formed to a thickness of about 1 nm to about 10 nm. The seed layer and the thin film may be formed by MOCVD, according to an in-situ process. The chalcogenide alloy may include a Ge, Sb, Te, Sb₂Te₃, or Sb-doped Ge alloy. The Group IV-precursor, the Group V-precursor and the Group VI-precursor may be a Ge-precursor, Sb-precursor and Te-precursor, respectively.

Each of the Group IV-precursor, the Group V-precursor, and the Group VI-precursor may be supplied at a flow rate of about 10 sccm to about 400 sccm. The seed layer and the thin film may be formed under a pressure of about 0.001 Torr to about 10 Torr and at a temperature of about 250° C. to about 500° C. When the seed layer is formed of Sb-doped Ge, a doping concentration of Sb with respect to Ge may be controlled to be about 1%-about 30%. The bottom electrode contact may be formed of one of TiN and TiAlN. The insulating film may include forming one of SiO₂, SiON, and Si₃N₄.

The Group IV-precursor includes at least one selected from the group consisting of (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄, and Ge[N(Si(CH₃)₃)₂]₄. The Group V-precursor includes at least one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and Sb[N(Si(CH₃)₃)₂]₃. The Group VI-precursor includes at least one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(CH₂═CH)₂, Te(CH₂CH═CH₂)₂, and Te[N(Si(CH₃)₃)₂]₂.

According to example embodiments, a thin film structure with improved crystallinity and/or surface morphology may be more easily formed on an amorphous material layer (e.g., an SiO₂ layer, an SiON layer and/or an Si₃N₄ layer) by MOCVD.

### BRIEF DESCRIPTION OF THE DRAWINGS

Example embodiments will be more clearly understood from the following detailed description taken in conjunction with the accompanying drawings. FIGS. 1-11 represent non-limiting, example embodiments as described herein.

FIGS. 1A, 1B, and 1C are diagrams illustrating a method of manufacturing a thin film according to example embodiments;

FIG. 2A is a scanning electron microscopic (SEM) picture of a surface of a seed layer formed of Sb;

FIG. 2B is an SEM picture of a surface of a seed layer formed of Sb₂Te₃;

FIGS. 3A and 3B are SEM pictures of a surface of a seed layer formed of Sb-doped Ge at about 300° C. and a surface of a seed layer formed of Sb-doped Ge at about 350° C., respectively;

FIGS. 4-6 are an XRD analysis graph, an AES analysis graph and an XPS analysis graph, respectively, of a seed layer formed of Sb-doped Ge at about 300° C.;

FIG. 7 is a diagram illustrating a phase-change random access memory (PRAM) device manufactured according to example embodiments;

FIG. 8 is a graph showing a binary information storing operation performed by the PRAM device of FIG. 7;

FIG. 9A through 9E are diagrams illustrating a method of manufacturing the PRAM device of FIG. 7 according to example embodiments;

FIG. 10 is a diagram illustrating a modification of a storage node manufactured according to the method illustrated in FIGS. 9A through 9E; and

FIG. 11 is a diagram illustrating another modification of the storage node manufactured according to the method illustrated in FIGS. 9A through 9E.

### DETAILED DESCRIPTION OF EXAMPLE EMBODIMENTS

Example embodiments will now be described more fully hereinafter with reference to the accompanying drawings, in which preferred embodiments are shown. Example embodiments may, however, be embodied in many different forms and should not be construed as being limited to the embodiments set forth herein. Rather, these embodiments are provided so that this disclosure will be thorough and complete, and will fully convey the scope of example embodiments to those skilled in the art. For clarification, the thickness of layers and regions illustrated in the drawings are overstated.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. The example term “below” can encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

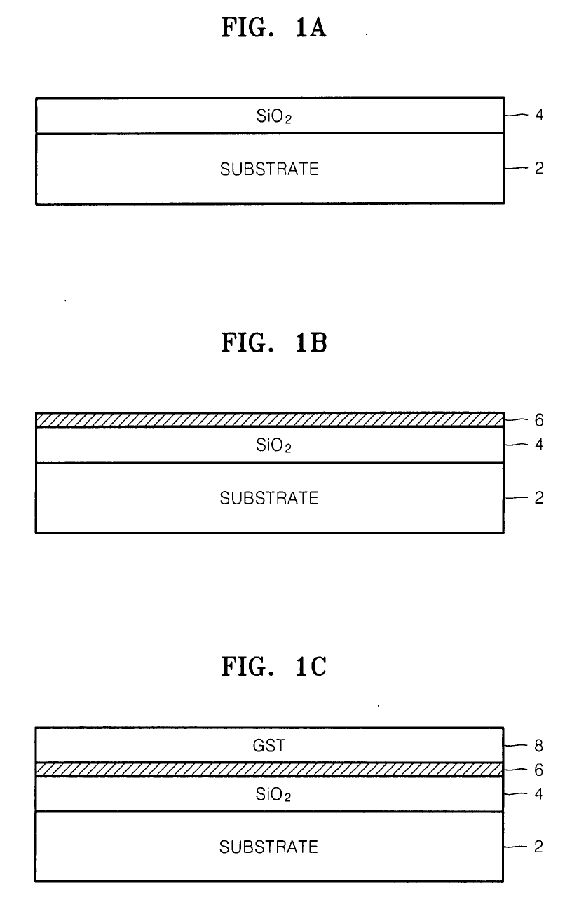

FIGS. 1A, 1B, and 1C are diagrams illustrating a method of manufacturing a thin film structure according to example embodiments. Referring to FIGS. 1A-1C, one or two selected from the group consisting of a Group IV-precursor, a Group V-precursor, and a Group VI-precursor may be supplied to a surface of an amorphous material layer 4 formed on a substrate 2, thereby forming a seed layer 6 made of a chalcogenide alloy, for example, a Ge, Sb, Te, Sb₂Te₃ and/or Sb-doped Ge alloy. A Group IV-precursor, a Group VI-precursor, and/or a Group V-precursor may be supplied to a surface of the seed layer 6 to thereby form a thin film 8. The seed layer 6 may have an improved adhesion to the amorphous material layer 4 and may provide a nucleation site for the formation of the thin film 8. The thin film 8 formed on the seed layer 6 may have improved surface morphology and crystallinity, so that an improved-quality thin film 8 may be manufactured. Because the seed layer 6 is formed of a material of the same type as the material of the thin film 8, the seed layer 6 and the thin film 8 may be adhered to each other, and while maintaining the vacuum state of a deposition chamber, depositions for forming the seed layer 6 and the thin film 8 may be consecutively performed according to an in-situ process.

The seed layer 6 may be formed to a thickness in a range of about 1 nm-about 10 nm and may be formed by MOCVD (Metal Organic Chemical Vapor Deposition). The seed layer 6 may be formed at a pressure range of about 0.001 Torr-about 10 Torr and a temperature range of about 250° C.-about 500° C. Under these process conditions, the surface property of the seed layer 6 formed on the amorphous material layer 4 may be improved and may affect the film quality of the thin film 8 deposited on the seed layer 6. The amorphous material layer 4 may include one selected from the group consisting of SiO₂, SiON and/or Si₃N₄, which may be used as a material for forming an interlayer insulating film in the manufacture of semiconductor devices.

The seed layer 6 may only provide a nucleation site and thus may not need to be as thick as about 10 nm or greater. Rather, the seed layer 6 may be formed relatively thin. When the seed layer 6 is formed of Sb-doped Ge, the doping concentration of Sb with respect to Ge may be in the range of about 1% to about 30%. In an experiment, when the seed layer 6 was formed with a doping concentration in the above range, the surface property of the seed layer 6 may be improved, and the film quality of the thin film 8 formed on the seed layer 6 may be improved.

In the MOCVD process, a Group VI-precursor, a Group IV-precursor, and a Group V-precursor may each be supplied at a flow rate in the range of about 10 sccm to about 400 sccm. The Group IV-precursor may include at least one selected from the group consisting of (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄ and/or Ge[N(Si(CH₃)₃)₂]₄. The Group V-precursor may include at least one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃ and/or Sb[N(Si(CH₃)₃)₂]₃. The Group VI-precursor may include at least one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(CH₂═CH)₂, Te(CH₂CH═CH₂)₂ and/or Te[N(Si(CH₃)₃)₂]₂.

The thin film 8 may be formed by MOCVD, the same as the seed layer 6. The process conditions for forming the thin film 8 may be similar to the process conditions for forming the seed layer 6. The thin film 8 may be formed at a pressure in the range of about 0.001 Torr-about 10 Torr and a temperature in the range of about 250° C. to about 500° C.

The thin film 8 may be formed of a GeSbTe-based chalcogenide material. For example, the thin film 8 may include a chalcogenide alloy, (e.g., germanium-antimony-tellurium (Ge—Sb—Te), nitrogen-germanium-antimony-tellurium (N—Ge—Sb—Te), arsenic-antimony-tellurium (As—Sb—Te), indium-antimony-tellurium (In—Sb—Te), germanium-bismuth-tellurium (Ge—Bi—Te), tin-antimony-tellurium (Sn—Sb—Te), silver-indium-antimony-tellurium (Ag—In—Sb—Te), gold-indium-antimony-tellurium (Au—In—Sb—Te), germanium-indium-antimony-tellurium (Ge—In—Sb—Te), selenium-antimony-tellurium (Se—Sb—Te), tin-indium-antimony-tellurium (Sn—In—Sb—Te) and/or arsenic-germanium-antimony-tellurium (As—Ge—Sb—Te)). Alternatively, the thin film 8 may include a Group VA element-antimony-tellurium (e.g., tantalum-antimony-tellurium (Ta—Sb—Te), niobium-antimony-tellurium (Nb—Sb—Te) and/or vanadium-antimony-tellurium (V—Sb—Te)) and/or Group VA element-antimony-selenium (e.g., tantalum-antimony-selenium (Ta—Sb—Se), niobium-antimony-selenium (Nb—Sb—Se) and/or vanadium-antimony-selenium (V—Sb—Se)). Alternatively, the thin film 8 may include a Group VIA element-antimony-tellurium (e.g., tungsten-antimony-tellurium (W—Sb—Te), molybdenum-antimony-tellurium (Mo—Sb—Te) and/or chromium-antimony-tellurium (Cr—Sb—Te)) and/or a Group VIA element-antimony-selenium (e.g., tungsten-antimony-selenium (W—Sb—Se), molybdenum-antimony-selenium (Mo—Sb—Se) and/or chromium-antimony-selenium (Cr—Sb—Se)).

Although it is described above that the thin film 8 may be formed of ternary phase-change chalcogenide alloys, the thin film 8 may be formed of binary phase-change chalcogenide alloys and/or quaternary phase-change chalcogenide alloys. The binary phase-change chalcogenide alloy may include one or more materials of Ga—Sb, Ge—Sb, In—Sb, In—Se, Sb₂—Te₃ and/or Ge—Te alloy. The ternary phase-change chalcogenide alloy may include one or more materials of Ag—In—Sb—Te, (Ge—Sn)—Sb—Te, Ge—Sb—(Se—Te) and/or Te₈₁—Ge₁₅—Sb₂—S₂ alloy.

It may be relatively difficult to form the thin film 8 on the SiO₂ material layer 4 using a conventional MOCVD process. When the seed layer 6 is formed before forming the thin film 8, the thin film 8 of improved quality may be able to be formed on the SiO₂ material layer 4 even though the plasma process may not be used. The thin film 8, having improved crystallinity and improved surface morphology, may be more easily formed on the amorphous material layer 4 (e.g., a SiO₂ layer, a Si₃N₄ layer and/or a SiON layer) by simple MOCVD. The seed layer 6 may be formed of a material of the same type as that of the material forming the thin film 8 using an in-situ process, so that the formation method of the thin film 8 may be simpler.

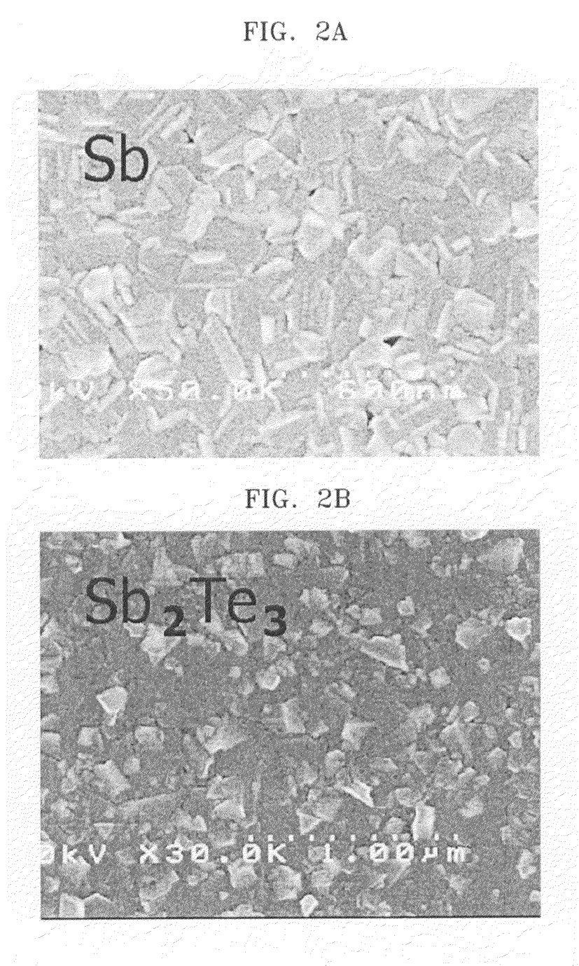

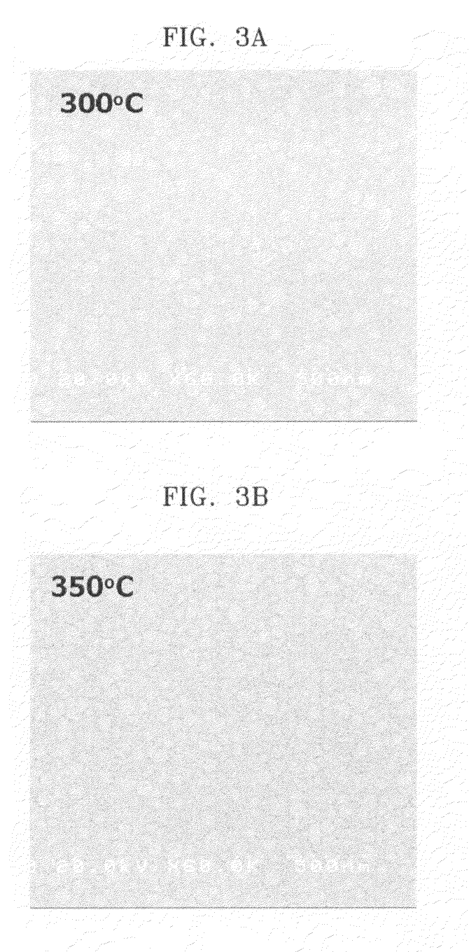

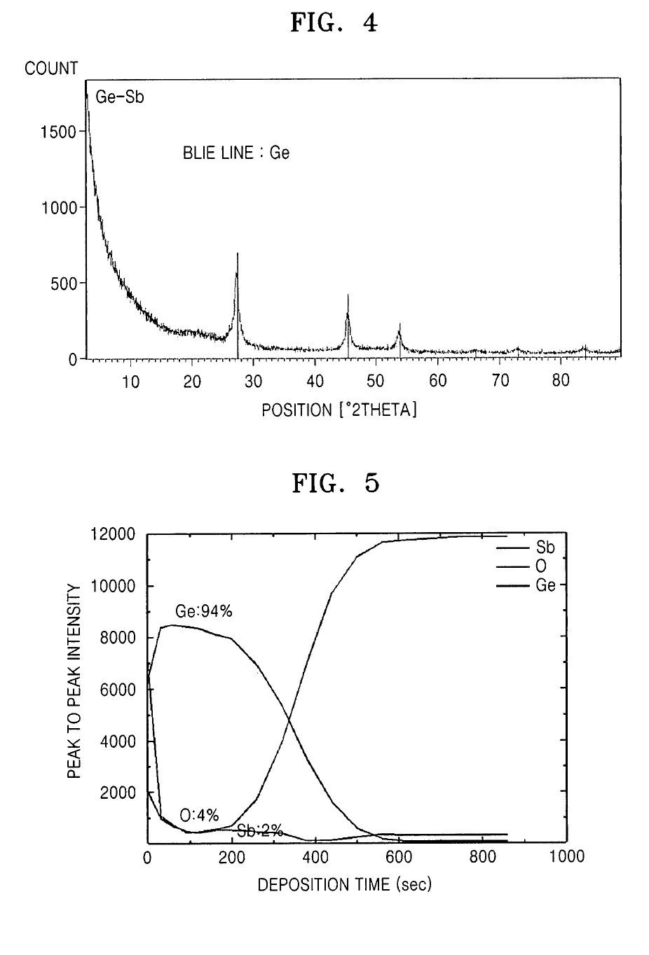

FIG. 2A is a scanning electron microscopic (SEM) picture of a surface of a seed layer formed of Sb according to example embodiments. FIG. 2B is an SEM picture of a surface of a seed layer formed of Sb₂Te₃ according to example embodiments. FIGS. 3A and 3B are SEM pictures of a surface of a seed layer formed of Sb-doped Ge at about 300° C. and a surface of a seed layer formed of Sb-doped Ge at about 350° C., respectively. Each of the seed layers of FIGS. 3A and 3B may be formed on a SiO₂ substrate.

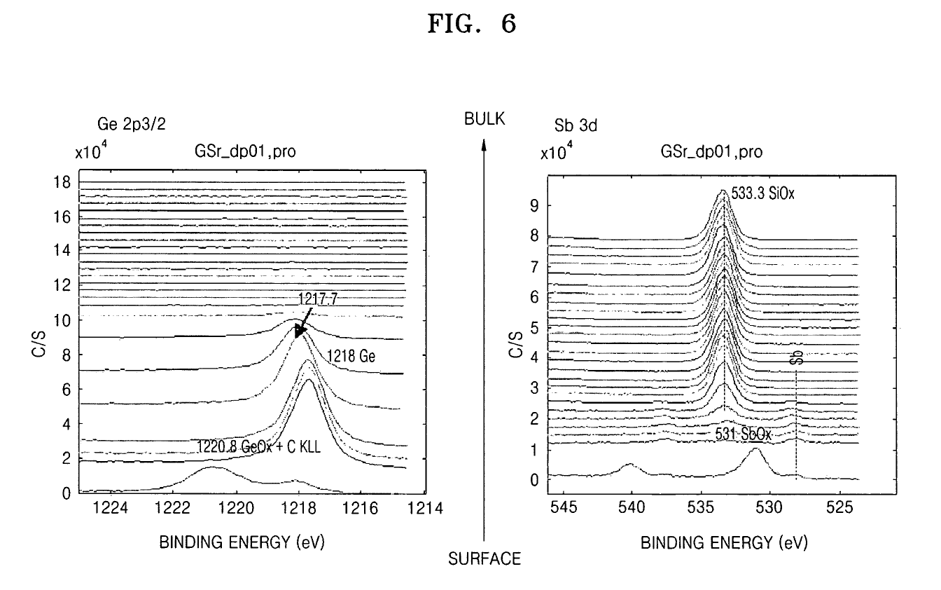

FIGS. 4, 5, and 6 are an XRD analysis graph, an AES analysis graph, and an XPS analysis graph, respectively, of a seed layer formed of Sb-doped Ge at about 300° C. The crystalline structure of the Sb-doped Ge thin film according to example embodiments may be known from FIG. 4. The composition of the Sb-doped Ge thin film may be known from FIG. 5. The chemical combination state of the Sb-doped Ge thin film may be known from FIG. 6. Referring to FIG. 6, an interface phase (i.e., 1217.7 eV) appearing as Ge—SiOx may be formed on an interface between Ge and SiO₂.

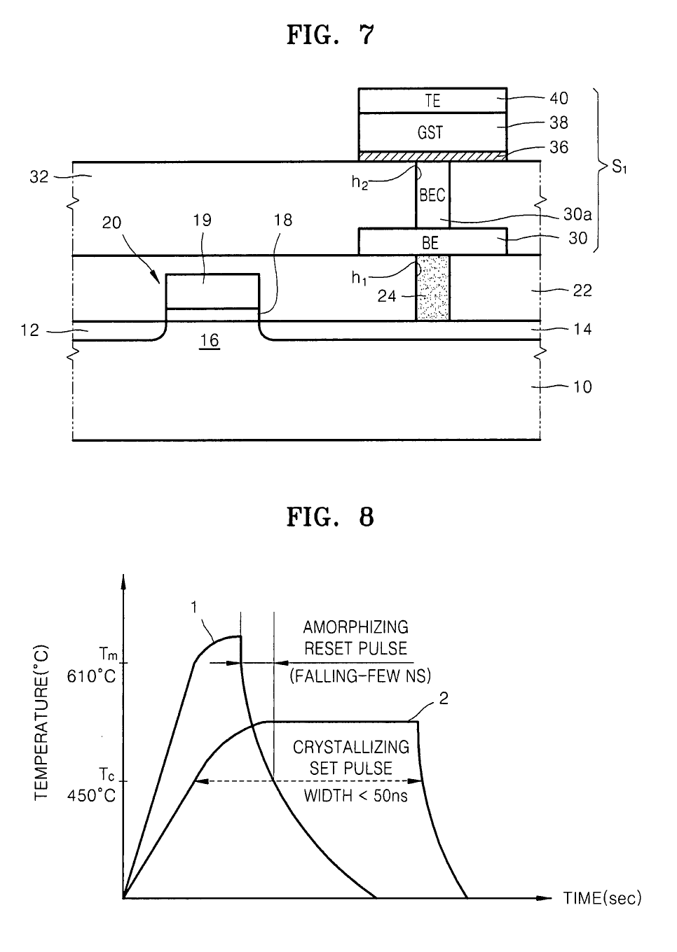

FIG. 7 is a diagram of a phase change random access memory (PRAM) manufactured according to example embodiments. Referring to FIG. 7, the PRAM may include a thin film switching device 20 formed on a substrate 10 and a storage node S1 connected to the thin film switching device 20. In FIG. 7, a switching transistor may be formed as the thin film switching device 20 formed on the substrate 10.

The switching transistor 20 may include a source region 12 doped with n-type impurities, a drain region 14 doped with n-type impurities, a channel region 16 between the source and drain regions 12 and 14 and a gate stack formed on the channel region 16. The gate stack may include a gate insulating film 18 and a gate electrode 19 that are sequentially stacked. A first insulating film 22 may be stacked on the switching transistor 20, and a first contact hole h₁ through which the drain region 14 is exposed may be formed in the first insulating film 22. A conductive plug 24 may be formed in the first contact hole h₁ and may connect the drain region 14 to the storage node S₁. The first insulating film 22 may be formed of a dielectric material (e.g., SiO₂, Si₃N₄ and/or SiON).

The storage node S₁ may include a bottom electrode (BE) 30, a bottom electrode contact (BEC) 30a, a seed layer 36, a thin film 38 and a top electrode (TE) 40 which are sequentially stacked. A second insulating layer 32 may be formed of a dielectric material (e.g., SiO₂, Si₃N₄ and/or SiON) on the BE 30. A second contact hole h₂ exposing a predetermined or given area of the BE 30 may be formed in the second insulating layer 32. The BEC 30a may be formed in the second contact hole h₂ to serve as a resistive heater. The seed layer 36 may be formed on the second insulating layer 32 and may cover the upper surface of the BEC 30a. The thin film 38 may be formed on the seed layer 36. The TE 40 may be formed on the thin film 38. The BEC 30a may serve as a resistive heater and thus may heat the thin film 38 according to a set or reset pulse which is applied to the BEC 30a. The BEC 30a may be formed of TiAlN and/or TiN. The BEC 30a may contact the thin film 38 in a relatively small area because it may have a smaller width than the upper surface of the BE 30. The heating efficiency of the thin film 38 may be improved.

The seed layer 36 may have improved adhesion to the BEC 30a formed of TiAlN and/or TiN and the second insulating layer 32 formed of SiO₂, SiON and/or Si₃N₄ and may provide a nucleation site for the formation of the thin film 38. The surface morphology and the crystallinity of the thin film 38 formed on the seed layer 36 may be enhanced to thereby manufacture the improved-quality thin film 38. Because the seed layer 6 is formed of a material of the same type as the material used to form the thin film 38, the seed layer 6 may also have improved adhesion to the thin film 38. The seed layer 36 may be formed of Ge, Sb, Te, Sb₂Te₃ and/or Sb-doped Ge and may be formed by MOCVD. The seed layer 36 may be formed to a thickness of about 1 nm to about 10 nm. The thin film 38 may be formed of a GeSbTe-based chalcogenide material.

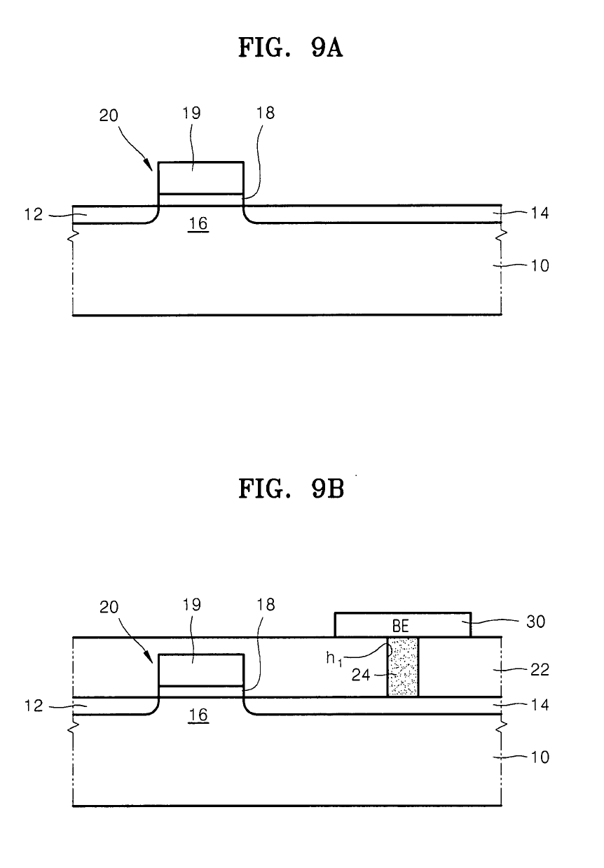

FIG. 8 is a graph showing a binary information storing operation performed by the PRAM of FIG. 7. A method of storing data in the storage node S₁ of the PRAM device and deleting the data therefrom will now be described with reference to FIG. 8. The horizontal axis indicates time (t), and the vertical axis indicates a temperature (whose unit is ° C.) which is generated in the thin film 38. A current in the form of a pulse may be applied to the PRAM and accordingly binary information may be recorded to the PRAM. The pulse may be a set pulse and/or a reset pulse according to the purpose of its use. The set pulse may be used to render the thin film 38 in a crystalline state and may have a width of about 50 ns or less. When the set pulse is used, a current with a size required to generate heat equal to or greater than a temperature used to crystallize a material may be applied. The reset pulse may be used to render the thin film 38 in an amorphous state, and a current with a size enough to generate heat equal to or greater than a temperature at which the material melts may be required. In the graph of FIG. 8, when the thin film 38 is heated up to a temperature higher then a melting temperature Tₘ for a relatively short period of time T₁ and then may be quenched at a relatively fast speed, the thin film 38 may change into the amorphous state (as indicated by a first curve 1). When the thin film 38 is heated at a temperature in between a crystallization temperature T_{c} and the melting temperature Tₘ for a period of time T₂ longer than T₁ and then quenched relatively slowly, the thin film 38 may change into the crystalline state (as indicated by a second curve 2). The resistivity of the thin film 38 in the amorphous state may be higher than the resistivity of the thin film 38 in the crystalline state. In a read mode, whether information stored in the PRAM storage node S₁ is logic “1” or logic “0” may be determined by detect the current flowing through the thin film 38.

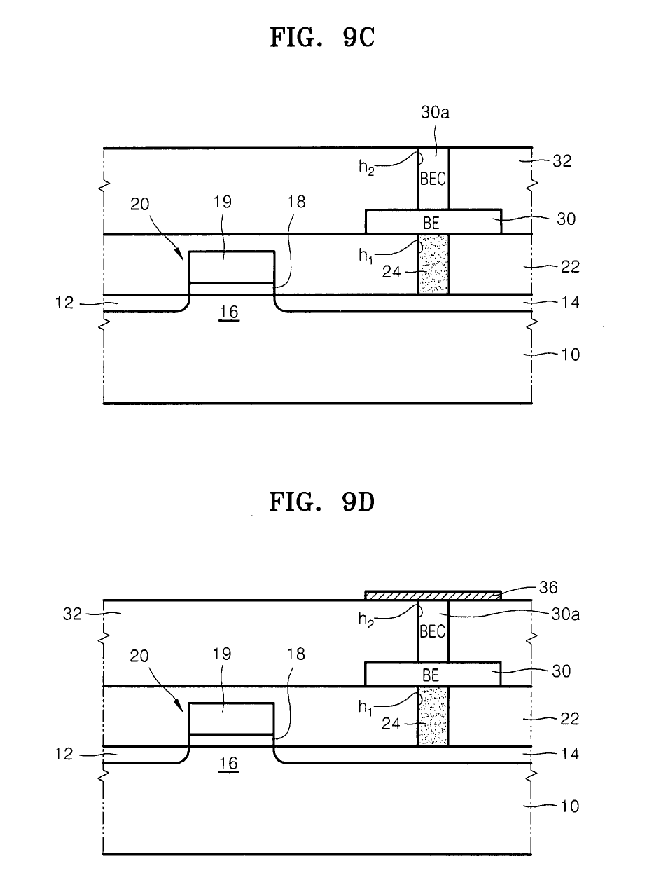

FIG. 9A-9E are diagrams illustrating a method of manufacturing the PRAM of FIG. 7 according to example embodiments. In this manufacturing process, each material layer may be formed by vapor deposition typically used in the manufacture of semiconductor memory devices (e.g., reactive sputtering, MOCVD (metal organic chemical vapor deposition), evaporation and/or any other process) which fall under the categories of CVD (chemical vapor deposition) and/or PVD (physical vapor deposition). Because these processes are well known, detailed descriptions thereof will be omitted.

Referring to FIG. 9A, a switching transistor may be formed on the substrate 10 to serve as the thin film switching element 20. A source area 12 and a drain region 14 may be formed by doping the silicon wafer 10 with n-type impurities. A channel region 16 may be formed between the source and drain regions 12 and 14. A gate insulating layer 18 and a gate electrode 19 may be sequentially stacked on the channel region 16, thereby realizing the switching transistor 20. The material used to form the switching transistor 20 and the formation method thereof may be already widely known, so detailed descriptions thereof will be omitted.

Referring to FIG. 9B, the first insulating layer 22 may be formed of a dielectric material (e.g., SiO₂, Si₃N₄ and/or SiON) on the switching transistor 20. The first contact hole h₁ exposing the drain region 14 may be formed in the first insulating film 22. Thereafter, the first contact hole h₁ may be filled with a conductive material to thereby form the conductive plug 24. The BE 30 may be formed on the first insulating film 22 and may contact the conductive plug 24. The formation method and the material of the BE 30 may be well known in the field of PRAM devices, so detailed descriptions thereof will be omitted. Referring to FIG. 9C, the second insulating film 32 may be formed of a dielectric material (e.g., SiO₂, Si₃N₄ and/or SiON) on the BE 30. The second contact hole h₂ exposing a predetermined or given area of the BE 30 may be formed in the second insulating film 32. The BEC 30a may be formed in the second contact hole h₂ to serve as a resistive heater. The BEC 30a may be formed of TiAlN and/or TiN.

Referring to FIGS. 9D and 9E, the seed layer 36 may be formed on the second insulating film 32 and may cover the upper surface of the BEC 30a. One or two selected from the group consisting of a Group IV-precursor, a Group V-precursor and a Te-precursor may be supplied to the upper surfaces of the BEC 32a and the second insulating film 32, thereby obtaining a seed layer 36 formed of Ge, Sb, Te, Sb₂Te₃ and/or Sb-doped Ge. The seed layer 36 may be formed by MOCVD (Metal Organic Chemical Vapor Deposition). The seed layer 36 may be formed to a thickness of about 1 nm-about 10 nm. The seed layer 36 may be formed under a temperature of about 250° C. to about 500° C. and a pressure of about 0.001 Torr to about 10 Torr. The seed layer 36 formed in this way may have improved adhesion to the BEC 32a and the second insulating film 32 and may be formed to a relatively uniform thickness although it is placed on two different kinds of surfaces. Thereafter, the Te—precursor, the Ge—precursor, and the Sb—precursor may be supplied to the upper surface of the seed layer 36, thereby forming the thin film 38.

The seed layer 36 may provide a nucleation site for the formation of the thin film 38, and thus the surface morphology and the crystallinity of the thin film 38 may be improved, resulting in an improved-quality thin film 38. The seed layer 36 may be formed of a material of the same type as that of a material used to form the thin film 38, and thus may have improved adhesion to the thin film 38. In addition, deposition processes for forming the seed layer 36 and the thin film 38 may be consecutively performed while maintaining the vacuum state of a deposition chamber by an in-situ process.

When the seed layer 36 is formed of Sb-doped Ge, the doping concentration of Sb with respect to Ge may be about 1% to about 30%. In an experiment, when the seed layer 36 was formed at the doping concentration range, the surface property of the seed layer 36 may be improved and the film quality of the thin film 38 formed on the seed layer 36 may be improved.

In the above MOCVD, each of the Group IV-precursor, the Group V-precursor and the Group VI-precursor may be supplied at a flowrate of about 10 sccm to about 400 sccm. The Group IV-precursor may include at least one selected from the group consisting of (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄ and/or Ge[N(Si(CH₃)₃)₂]₄. The Group V-precursor may include at least one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃ and/or Sb[N(Si(CH₃)₃)₂]₃. The Group VI-precursor may include at least one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(CH₂═CH)₂, Te(CH₂CH═CH₂)₂ and/or Te[N(Si(CH₃)₃)₂]₂. The thin film 38 may be formed by MOCVD like the seed layer 36. The process conditions for the thin film 38 may be similar to those for the seed layer 36. The thin film 38 may be formed at a temperature of about 250° C. to about 500° C. and a pressure of about 0.001 Torr to about 10 Torr.

The thin film 38 may be formed of a GeSbTe-based chalcogenide material. For example, the thin film 38 may include chalcogenide alloys, (e.g., germanium-antimony-tellurium (Ge—Sb—Te), nitrogen-germanium-antimony-tellurium (N—Ge—Sb—Te), arsenic-antimony-tellurium (As—Sb—Te), indium-antimony-tellurium (In—Sb—Te), germanium-bismuth-tellurium (Ge—Bi—Te), tin-antimony-tellurium (Sn—Sb—Te), silver-indium-antimony-tellurium (Ag—In—Sb—Te), gold-indium-antimony-tellurium (Au—In—Sb—Te), germanium-indium-antimony-tellurium (Ge—In—Sb—Te), selenium-antimony-tellurium (Se—Sb—Te), tin-indium-antimony-tellurium (Sn—In—Sb—Te) and/or arsenic-germanium-antimony-tellurium (As—Ge—Sb—Te)). Alternatively, the thin film 8 may include a Group VA element-antimony-tellurium (e.g., tantalum-antimony-tellurium (Ta—Sb—Te), niobium-antimony-tellurium (Nb—Sb—Te) and/or vanadium-antimony-tellurium (V—Sb—Te)) and/or a Group VA element-antimony-selenium (e.g., tantalum-antimony-selenium (Ta—Sb—Se), niobium-antimony-selenium (Nb—Sb—Se) and/or vanadium-antimony-selenium (V—Sb—Se)). Alternatively, the thin film 8 may include a Group VIA element-antimony-tellurium (e.g., tungsten-antimony-tellurium (W—Sb—Te), molybdenum-antimony-tellurium (Mo—Sb—Te) and/or chromium-antimony-tellurium (Cr—Sb—Te)) and/or a Group VIA element-antimony-selenium (e.g., tungsten-antimony-selenium (W—Sb—Se), molybdenum-antimony-selenium (Mo—Sb—Se) and/or chromium-antimony-selenium (Cr—Sb—Se)).

Although it is described above that the thin film 8 may be formed of ternary phase-change chalcogenide alloys, the thin film 8 may be formed of binary phase-change chalcogenide alloys and/or quaternary phase-change chalcogenide alloys. The binary phase-change chalcogenide alloy may include one or more materials of a Ga—Sb, Ge—Sb, In—Sb, In—Se, Sb₂—Te₃ and/or Ge—Te alloy. The ternary phase-change chalcogenide alloy may include one or more materials of an Ag—In—Sb—Te, (Ge—Sn)—Sb—Te, Ge—Sb—(Se—Te) and/or Te₈₁—Ge₁₅—Sb₂—S₂ alloy. The TE 40 may be formed on the thin film 38. The material used to form the TE 40 and the formation method thereof may be known in the field of PRAM device manufacturing processes, so detailed descriptions thereof will be omitted.

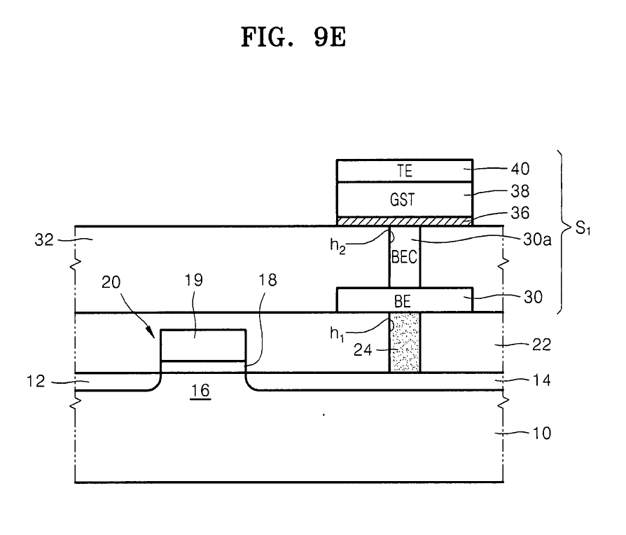

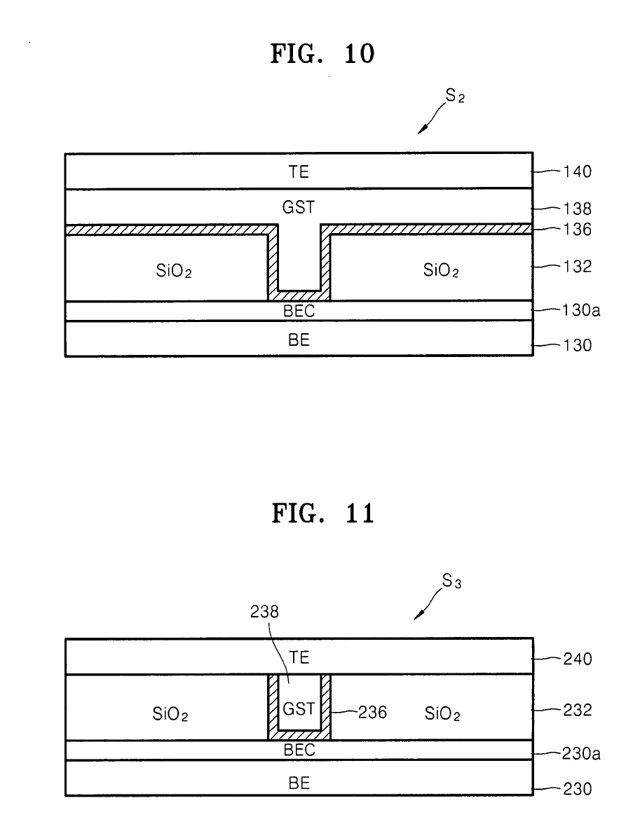

FIG. 10 is a diagram of a modification S₂ of a storage node manufactured according to the method illustrated in FIGS. 9A through 9E. FIG. 11 is a diagram of another modification S₃ of the storage node manufactured according to the method illustrated in FIGS. 9A through 9E. Referring to the storage node S₂ of FIG. 10, a BEC 130a and an insulating film 132 may be sequentially stacked on a BE 130. A contact hole exposing a predetermined or given area of the BEC 130a may be formed in the insulating film 132. A seed layer 136 may be relatively thinly formed on the inner surface of the contact hole and on the insulating film 132. A thin film 138 may be formed on the seed layer 136 and may fill up the contact hole. A TE 140 may be formed on the thin film 138.

Referring to the storage node S₃ of FIG. 11, a BEC 230a and an insulating film 232 may be sequentially stacked on a BE 230. A contact hole exposing a predetermined or given area of the BEC 230a may be formed in the insulating film 232. A seed layer 236 may be relatively thinly formed on the inner surface of the contact hole. A thin film 238 may be formed on the seed layer 236 and may fill up the contact hole. A TE 240 may be formed on the insulating film 232 and may cover the thin film 238. The materials used to form the BEs 130 and 230, the BECs 130a and 230a, the seed layers 136 and 236, the thin films 138 and 238, and the TEs 140 and 240, and the insulating layers 132 and 232 are already described above, so descriptions thereof will be omitted.

It may be relatively difficult to form a thin film on a SiO₂ substrate using a conventional MOCVD process. When a seed layer is formed prior to forming the thin film, an improved-quality thin film may be formed on the SiO₂ substrate even when a plasma process is not used. A thin film with an improved surface morphology and improved crystallinity may be more easily formed on an amorphous material layer (e.g., a SiO₂ layer, a Si₃N₄ layer and/or an SiON layer) using a MOCVD process. The seed layer may be formed of a material of the same type as the material used to form the thin film and thus may be formed by an in-situ process. The formation of the thin film according to example embodiments may be relatively simple. When a PRAM device including a thin film is manufactured using the same method as the thin film forming method according to example embodiments, it may be possible to form a improved-quality thin film on two different types of surfaces, for example, an insulating film formed of SiON and/or SiO₂ and a BEC formed of TiAlN and/or TiN, to a relatively uniform thickness at the same time. Thus, the reliability and the reproducibility of the PRAM device may be improved.

While example embodiments have been particularly shown and described with reference to exemplary embodiments thereof, it will be understood by those of ordinary skill in the art that various changes in form and details may be made therein without departing from the spirit and scope of the following claims.

What is claimed is:

1. A method of manufacturing a thin film structure, comprising:
forming a seed layer formed of a chalcogenide alloy, by supplying one or two selected from the group consisting of a Group IV-precursor, a Group V-precursor, and a Group VI-precursor to an upper surface of an amorphous material layer; and
forming the thin film by supplying a Group IV-precursor, a Group V-precursor, and a Group VI-precursor to an upper surface of the seed layer.

2. The method of claim 1, wherein forming the seed layer includes forming the seed layer of a Ge, Sb, Te, Sb₂Te₃, or Sb-doped Ge alloy.

3. The method of claim 1, wherein the Group IV-precursor, the Group V-precursor and the Group VI-precursor are a Ge-precursor, Sb-precursor and Te-precursor, respectively.

4. The method of claim 1, wherein the amorphous material layer includes one of SiO₂, SiON, and Si₃N₄.

5. The method of claim 1, wherein forming the seed layer includes forming the seed layer at a thickness of about 1 nm to about 10 nm.

6. The method of claim 1, wherein forming the seed layer and the thin film includes forming the seed layer and the thin film by MOCVD (metal organic chemical vapor deposition).

7. The method of claim 1, wherein forming the seed layer and the thin film includes forming the seed layer and the thin film according to an in-situ process.

8. The method of claim 1, wherein supplying each of the Group IV-precursor, the Group V-precursor, and the Group VI-precursor includes supplying each of the Group IV-precursor, the Group V-precursor, and the Group VI-precursor at a flow rate of about 10 sccm to about 400 sccm.

9. The method of claim 1, wherein forming the seed layer and the thin film includes forming the seed layer and the thin film under a pressure of about 0.001 Torr to about 10 Torr.

10. The method of claim 1, wherein forming the seed layer and the thin film includes forming the seed layer and the thin film at a temperature of about 250° C. to about 500° C.

11. The method of claim 2, wherein the seed layer includes Sb-doped Ge, wherein a doping concentration of Sb with respect to Ge is about 1%-about 30%.

12. The method of claim 1, wherein supplying the Group IV-precursor includes supplying at least one selected from the group consisting of (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄, and Ge[N(Si(CH₃)₃)₂]₄.

13. The method of claim 1, wherein supplying the Group V-precursor includes supplying at least one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and Sb[N(Si(CH₃)₃)₂]₃.

14. The method of claim 1, wherein supplying the Group VI-precursor includes supplying at least one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(CH₂═CH)₂, Te(CH₂CH═CH₂)₂, and Te[N(Si(CH₃)₃)₂]₂.

15. A method of manufacturing a storage node comprising:
forming a bottom electrode;
forming an insulating film on the bottom electrode;
exposing a predetermined or given area of the bottom electrode through a contact hole in the insulating film;
forming a bottom electrode contact in the contact hole;
manufacturing the thin film structure according to claim 1; and
forming a top electrode on the thin film structure.

16. A method of manufacturing a phase-change random access memory (PRAM) comprising:
forming a thin film switching device on a substrate; and
forming the storage node according to claim 15 connected to the thin film switching device.

17. The method of claim 15, wherein forming the bottom electrode contact includes forming the bottom electrode contact of one of TiN and TiAlN.

18. The method of claim 15, wherein forming the insulating film includes forming one of SiO₂, SiON, and Si₃N₄.

19. A thin film structure, comprising:
a seed layer including a chalcogenide alloy on an upper surface of an amorphous material layer; and
a thin film on an upper surface of the seed layer.

20. A thin film structure according to claim 19, wherein the chalcogenide alloy includes one of Ge, Sb, Te, Sb₂Te₃ or Sb-doped Ge.

21. A thin film structure according to claim 19, wherein the thin film is formed from a Group IV-precursor, a Group V-precursor, and a Group VI-precursor.

22. A storage node comprising:
a bottom electrode;
an insulating film on the bottom electrode;
a bottom electrode contact in a contact hole through the insulating film;
the thin film structure of claim 19 on the bottom electrode contact; and
a top electrode on the thin film structure.

23. The storage node of claim 22, wherein the bottom electrode contact includes one of TiN and TiAlN.

24. The storage node of claim 22, wherein the insulating film includes one of SiO₂, SiON, and Si₃N₄.

25. A phase-change random access memory (PRAM) comprising:
a thin film switching device on a substrate; and
the storage node according to claim 22 connected to the thin film switching device.

26. The thin film structure according to claim 19, wherein the seed layer is formed at a thickness of about 1 nm to about 10 nm.

27. The thin film structure according to claim 19, wherein the seed layer and the thin film are formed by MOCVD (metal organic chemical vapor deposition).

28. The thin film structure according to claim 19, wherein the seed layer and the thin film are formed according to an in-situ process.

29. The thin film structure according to claim 19, wherein each of the Group IV-precursor, the Group V-precursor, and the Group VI-precursor is supplied at a flow rate of about 10 sccm to about 400 sccm.

30. The thin film structure according to claim 19, wherein the seed layer and the thin film are formed under a pressure of about 0.001 Torr to about 10 Torr.

31. The thin film structure according to claim 19, wherein the seed layer and the thin film are formed at a temperature of about 250° C. to about 500° C.

32. The thin film structure according to claim 20, wherein when the seed layer is formed of Sb-doped Ge, a doping concentration of Sb with respect to Ge is about 1%-about 30%.

33. The thin film structure according to claim 19, wherein the Group IV-precursor includes at least one selected from the group consisting of (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄, and Ge[N(Si(CH₃)₃)₂]₄.

34. The thin film structure according to claim 19, wherein the Group V-precursor includes at least one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and Sb[N(Si(CH₃)₃)₂]₃.

35. The thin film structure according to claim 19, wherein the Group VI-precursor includes at least one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(CH₂═CH)₂, Te(CH₂CH═CH₂)₂, and Te[N(Si(CH₃)₃)₂]₂.
